(19) United States
(12) Patent Application Publication
(10) Pub. No.: US 2026/0197943 A1
(43) Pub. Date: Jul. 9, 2026

(54) OPTICAL APPARATUS

(71) Applicant: CANON KABUSHIKI KAISHA, Tokyo (JP)

(72) Inventors: MITSURU MOROHASHI, Tokyo (JP); KANAE NAKAMORI, Kanagawa (JP); AKIRA TAKAURA, Kanagawa (JP); KOHEI MATSUMOTO, Chiba (JP)

(21) Appl. No.: 19/556,418

(22) Filed: Mar. 4, 2026

Related U.S. Application Data
(63) Continuation of application No. PCT/JP2024/028957, filed on Aug. 14, 2024.

(30) Foreign Application Priority Data
Sep. 15, 2023 (JP) 2023-149726

(51) Int. Cl. H05K 1/14

(52) U.S. Cl. CPC H05K 1/141; H05K 1/147; H05K 2201/09027

(57) ABSTRACT

An optical apparatus may include a first substrate having a principal plane perpendicular to an optical axis, a second substrate having a principal plane parallel to the optical axis, and a flexible printed circuit. The first substrate and the second substrate may be joined to each other. When viewed in an optical-axis direction, the second substrate may overlap the flexible printed circuit.

### CROSS-REFERENCE TO RELATED APPLICATIONS

This application is a Continuation of International Patent Application No. PCT/JP2024/028957, filed on August 14, 2024, which claims the benefit of Japanese Patent Applications No. 2023-149726, filed on September 15, 2023, which is hereby incorporated by reference herein in their entirety.

### BACKGROUND

### Field of the Technology

The present disclosure relates to an optical apparatus.

### Description of the Related Art

With improvements in functions such as an autofocus (AF) function and an image stabilizing function in an optical apparatus such as an interchangeable lens, the scale of a control circuit mounted on a substrate inside the optical apparatus increases, and the substrate area increases. Japanese Patent Application Laid-Open No. 2003-172863 discloses an electrical substrate mounting structure including at least one rigid board disposed substantially perpendicular to an optical axis, at least one rigid board disposed substantially parallel to the optical axis, and a board-to-board connector that connects both rigid boards.

However, the structure disclosed in Japanese Patent Application Laid-Open No. 2003-172863 cannot place the electric substrates with high space efficiency, and therefore it is difficult to reduce the size of the optical apparatus.

### SUMMARY

An optical apparatus according to one aspect of the present disclosure may include a first substrate having a principal plane perpendicular to an optical axis, a second substrate having a principal plane parallel to the optical axis, and a flexible printed circuit. The first substrate and the second substrate may be joined to each other. When viewed in an optical-axis direction, the second substrate may overlap the flexible printed circuit.

Features of the present disclosure will become apparent from the following description of embodiments with reference to the attached drawings. The following description of embodiments will be described by way of example.

### BRIEF DESCRIPTION OF THE DRAWINGS

FIGS. 1A and 1B are external views of an imaging system according to the present embodiment.

FIG. 2 is a block diagram of the imaging system according to the present embodiment.

FIG. 3 is a sectional view of the imaging system according to the present embodiment (retracted state).

FIG. 4 is a sectional view of the imaging system according to the present embodiment (extended state).

FIGS. 5A and 5B are perspective views illustrating a state in which a first substrate, a second substrate, and a third substrate are joined according to the present embodiment.

FIGS. 6A and 6B are a rear view and a sectional view of an interchangeable lens with a first substrate exposed according to the present embodiment.

FIG. 7 is a perspective view of the first substrate, an image-side zoom unit, and a linear guide barrel according to the present embodiment.

FIGS. 8A, 8B, and 8C are detailed views of a fixing portion between the linear guide barrel and a flexible printed circuit (FPC) according to the present embodiment.

FIGS. 9A and 9B are perspective views of the first substrate, zoom unit, and FPC according to the present embodiment.

FIGS. 10A and 10B are a rear view and a sectional view of the first substrate and the FPC according to the present embodiment.

FIGS. 11A and 11B are a side view and a sectional view of the first substrate and the FPC according to the present embodiment.

### DESCRIPTION OF THE EMBODIMENTS

Hereinafter, embodiments of the present invention will be described in detail with reference to the drawings. In the drawings, the same reference numerals will be designated by the same reference numerals, and a duplicate description thereof will be omitted. In the present embodiment, an interchangeable lens (lens apparatus) is described as an example of an optical apparatus; however, the present embodiment is not limited to this example and is also applicable to other optical apparatuses such as a lens-integrated camera.

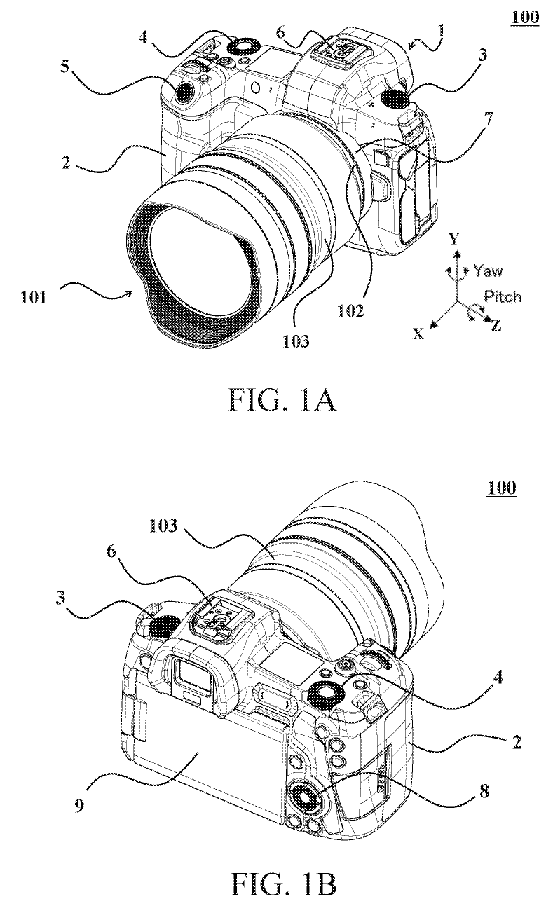

FIGS. 1A and 1B are external views of an imaging system (camera system) 100 according to the present embodiment. FIG. 1A is a perspective view viewed from the front side, and FIG. 1B is a perspective view viewed from the rear side. The imaging system 100 includes a camera body (digital camera) 1 and an interchangeable lens (lens apparatus, optical apparatus) 101 that is detachably attached to the camera body 1.

As illustrated in FIG. 1A, a direction in which an optical axis of an imaging optical system housed in the interchangeable lens 101 extends is defined as an X-axis direction. Two directions that are orthogonal to the optical axis and orthogonal to each other are defined as a Z-axis direction (horizontal direction) and a Y-axis direction (vertical direction). Hereinafter, the Z-axis direction and the Y-axis direction may collectively be referred to as a Z/Y-axis direction. A rotation direction about the Z-axis will be referred to as a pitch direction, and a rotation direction about the Y-axis is referred to as a yaw direction. The pitch direction and the yaw direction (pitch/yaw directions) are rotation directions about two orthogonal axes, namely the Z-axis and the Y-axis.

On the camera body 1, a grip portion 2 for a user to hold the camera body 1 by hand is provided on a left side when viewed from the front (a right side when viewed from the rear). A power operation unit 3 is provided on a top surface of the camera body 1. When the user turns on the power operation unit 3 while the camera body 1 is in a power-off state, the camera body 1 enters a power-on state and imaging becomes possible. When the user turns off the power operation unit 3 while the camera body 1 is in a power-on state, the camera body 1 enters a power-off state.

On the top surface of the camera body 1, a mode dial 4, a release button 5, and an accessory shoe 6 are provided. By rotating the mode dial 4, the user can switch an imaging mode. The imaging mode includes a manual still image capturing mode in which an imaging condition such as a shutter speed and an aperture value (F-number) can be arbitrarily set by the user, an automatic still image capturing mode in which a proper exposure amount is automatically obtained, and a moving image capturing mode for capturing a moving image. When the user half-presses the release button 5, an imaging preparation operation such as AF and auto-exposure (AE) control are instructed, and when the user fully presses the release button 5, an imaging is instructed. An accessory such as an external flash or an external viewfinder (EVF), not illustrated, is detachably attached to the accessory shoe 6. The camera body 1 includes an image sensor that photoelectrically converts (captures) an object image formed by the imaging optical system in the interchangeable lens 101.

The interchangeable lens 101 is mechanically and electrically connected to a camera mount 7 provided on the camera body 1 via a lens mount 102. As described above, the interchangeable lens 101 houses an imaging optical system that forms an object image by capturing light from an object. A zoom operation ring 103 that is rotatable about the optical axis by a user operation is provided on an outer circumference of the interchangeable lens 101. A knurled shape is formed on an outer peripheral portion of the zoom operation ring 103 to prevent slipping during user operation. When the zoom operation ring 103 is rotated by the user, a zoom lens unit constituting the imaging optical system moves to a predetermined optical position corresponding to the rotation angle of the zoom operation ring 103. Thus, the user can perform imaging with a desired angle of view.

As illustrated in FIG. 1B, a rear operation unit 8 and a display unit 9 are provided on a rear surface of the camera body 1. The rear operation unit 8 includes a plurality of buttons and dials to which various functions are assigned. When the camera body 1 is powered on and a still or moving image capturing mode is set, a live-view image of an object captured by the image sensor is displayed on the display unit 9. The display unit 9 also displays an imaging parameter such as a shutter speed and an aperture value, and the user can change a set value of the imaging parameter by operating the rear operation unit 8 while viewing the display. The rear operation unit 8 includes a playback button for instructing playback of a recorded captured image, and when the user operates the playback button, the captured image is displayed on the display unit 9.

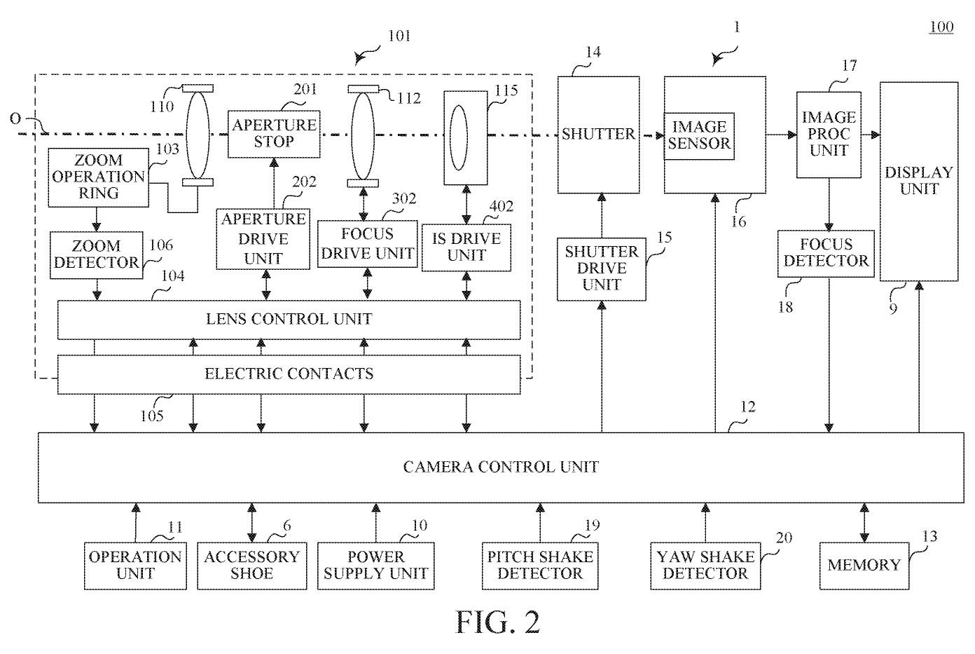

FIG. 2 is a block diagram illustrating electrical and optical configurations of the imaging system 100. The camera body 1 includes a power supply unit 10 that supplies power to the camera body 1 and the interchangeable lens 101, the power operation unit 3, the mode dial 4, the release button 5, and an operation unit 11 including the rear operation unit 8 and a touch panel function of the display unit 9. Overall system control of the camera body 1 and the interchangeable lens 101 is performed by cooperation between a camera control unit 12 provided in the camera body 1 and a lens control unit 104 provided in the interchangeable lens 101.

The camera control unit 12 reads and executes a computer program stored in a memory 13. At that time, the camera control unit 12 communicates various control signals and data with the lens control unit 104 via communication terminals of electrical contacts 105 provided on the lens mount 102. The electrical contacts 105 include a power supply terminal for supplying power from the power supply unit 10 to the interchangeable lens 101.

The imaging optical system in the interchangeable lens 101 includes a zoom lens unit 110 that is coupled to the zoom operation ring 103 and moves in the optical axis direction to change an angle of view, and an image stabilizing lens unit 115 including a shift lens serving as an image stabilizing element that reduces image blur. The image stabilizing lens unit 115 performs an image stabilizing operation by shifting the shift lens in the Z/Y-axis directions orthogonal to the optical axis O. The imaging optical system further includes an aperture unit (aperture stop, diaphragm) 201 that performs a light amount adjustment operation, and a focus lens unit 112, which is a moving lens unit including a focus lens that moves in the optical axis direction to perform focus adjustment. The interchangeable lens 101 includes an image-stabilization (IS) drive unit 402 that drives the image stabilizing lens unit 115 to shift the shift lens, an aperture drive unit 202 that drives the aperture unit 201, and a focus drive unit 302 that drives the focus lens unit 112 to move the focus lens.

The camera body 1 includes a shutter unit 14, a shutter drive unit 15, an image sensor 16, an image processing unit 17, and the camera control unit 12 described above. The shutter unit 14 controls an amount of light collected by the imaging optical system in the interchangeable lens 101 and exposed onto the image sensor 16. The image sensor 16 includes, for example, a Complementary Metal-Oxide-Semiconductor (CMOS) sensor, and photoelectrically converts an object image (optical image) formed by the imaging optical system to output an imaging signal. The image processing unit 17 performs a variety of image processing operations on the imaging signal and generates an image signal. The display unit 9 displays an image signal (live-view image) output from the image processing unit 17, displays the imaging parameter described above, or plays back and displays a captured image recorded in the memory 13 or a recording medium not illustrated.

The camera control unit 12 controls driving of the aperture unit 201 and the shutter unit 14 via the aperture drive unit 202 and the shutter drive unit 15 in accordance with set values of the aperture value and shutter speed received from the operation unit 11. The camera control unit 12 also controls driving of the focus lens unit 112 in accordance with an imaging preparation operation (half-press operation) performed on the operation unit 11 (release button 5).

For example, when an AF operation is instructed, a focus detector 18 determines a focus state of an object image formed on the image sensor 16 based on an image signal generated by the image processing unit 17, generates a focus signal, and transmits the focus signal to the camera control unit 12. At the same time, a focus drive unit 302 detects a current position of the focus lens unit 112 and transmits a signal indicating the detected position to the camera control unit 12 via the lens control unit 104. The camera control unit 12 compares the focus state of the object image with the current position of the focus lens unit 112, calculates a focus drive amount based on a deviation therebetween, and transmits the calculated focus drive amount to the lens control unit 104. The lens control unit 104 then controls driving of the focus lens unit 112 via the focus drive unit 302 to move the focus lens unit 112 to a target position, thereby correcting a focus shift of the object image.

In a case where an auto-exposure control operation is instructed, the camera control unit 12 receives a luminance signal generated by the image processing unit 17 and performs a photometric (or light metering) calculation. Based on a result of the photometric calculation, the camera control unit 12 controls driving of the aperture unit 201 in accordance with an imaging instruction operation (full-press operation) performed on the operation unit 11 (release button 5). At the same time, the camera control unit 12 controls driving of the shutter unit 14 via the shutter drive unit 15 to perform an exposure process by the image sensor 16.

The camera body 1 includes a pitch shake detector 19 and a yaw shake detector 20 as shake detectors capable of detecting image blur caused by camera shake by a user. Each of the pitch shake detector 19 and the yaw shake detector 20 uses an angular velocity sensor (vibration gyro) or an angular acceleration sensor to detect image blur in a pitch direction (rotation direction about the Z-axis) and a yaw direction (rotation direction about the Y-axis), respectively, and outputs a shake signal. The camera control unit 12 calculates a shift position of the image stabilizing lens unit 115 (shift lens) in the Y-axis direction using the shake signal from the pitch shake detector 19. Similarly, the camera control unit 12 calculates a shift position of the image stabilizing lens unit 115 in the Z-axis direction using the shake signal from the yaw shake detector 20. The camera control unit 12 then controls driving of the image stabilizing lens unit 115 to a target position in accordance with the calculated shift positions in the pitch/yaw directions, thereby performing an image stabilization operation that reduces image blur during exposure and during live-view image display.

The interchangeable lens 101 includes a zoom operation ring 103 for changing an angle of view of the imaging optical system, and a zoom detector 106 for detecting a rotation angle of the zoom operation ring 103. The zoom detector 106 detects, as an absolute value, the rotation angle of the zoom operation ring 103 operated by the user, and is configured using, for example, a resistive linear potentiometer. Information on the angle of view detected by the zoom detector 106 is transmitted to the lens control unit 104 and reflected in various types of control performed by the camera control unit 12 described above. On the other hand, part of various types of information is recorded together with a captured image in the memory 13 or a recording medium.

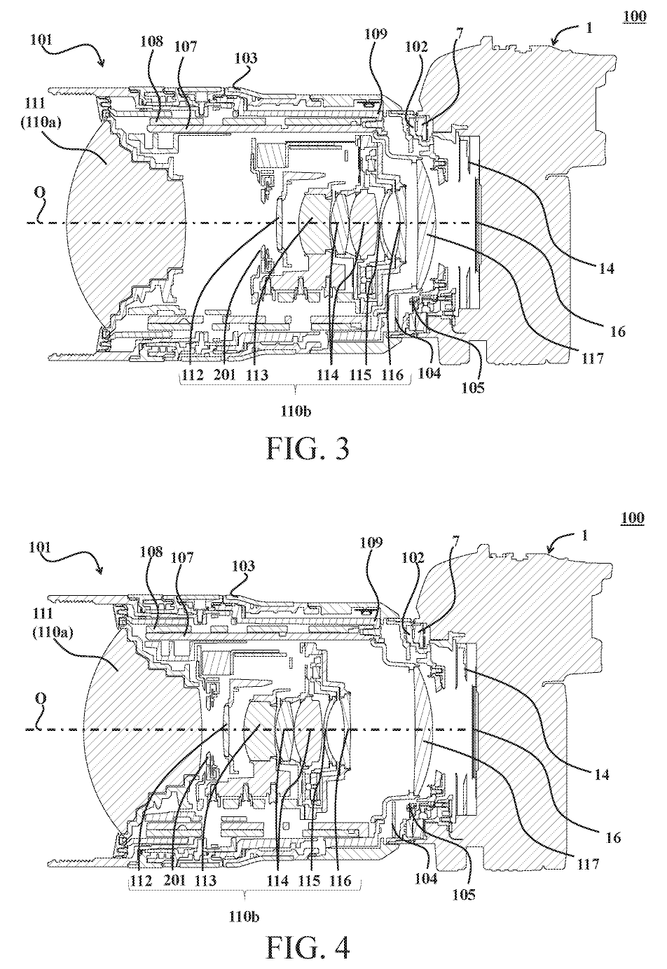

Next, positional relationships among components of the imaging system 100 will be described with reference to FIGS. 3 and 4. FIGS. 3 and 4 are cross-sectional views of the imaging system 100 on an XY plane including the optical axis. FIG. 3 illustrates a zoom-retracted state of the interchangeable lens 101, and FIG. 4 illustrates a zoom-extended state.

In the present embodiment, a seven-unit configuration is employed as an example of the imaging optical system. Each zoom lens unit that has moved to a predetermined optical position corresponding to an angle of view forms an image of light from an object on an imaging surface of the image sensor 16. At this time, the focus lens unit 112 functions as a second zoom lens unit, and the image stabilizing lens unit 115 functions as a fifth zoom lens unit. The imaging optical system further includes a first zoom lens unit 111, the aperture unit 201, a third zoom lens unit 113, a fourth zoom lens unit 114, a sixth zoom lens unit 116, and a seventh fixed lens unit 117.

The zoom lens unit 110 in the imaging optical system includes an object-side zoom lens unit 110a and an image-side zoom lens unit 110b. The object-side zoom lens unit 110a includes the first zoom lens unit 111. The image-side zoom lens unit 110b includes the second zoom lens unit 112, the third zoom lens unit 113, the fourth zoom lens unit 114, the fifth zoom lens unit 115, the sixth zoom lens unit 116, and the aperture unit 201, which are connected to one another.

The present embodiment does not limit the lens-unit configuration. For example, the image stabilizing lens unit 115 may function as a third zoom lens unit. In addition, some of the lens units may be fixed rather than movable.

A linear guide barrel 107 is a fixed member that is fixed to a fixed barrel 109 and is fixed to the lens mount 102 via the fixed barrel 109. On an outer peripheral surface of the linear guide barrel 107, bayonet claws (not illustrated) are arranged at equally spaced positions. On the other hand, a circumferential groove (not illustrated) is formed on an inner circumference surface of a cam barrel 108. The cam barrel 108 is connected to the zoom operation ring 103. When the zoom operation ring 103 is rotationally operated, the cam barrel 108 rotates about the optical axis due to engagement between the bayonet claws and the circumferential groove.

The linear guide barrel 107 has linear guide grooves that restrict the movement of each zoom lens unit in a rotational direction and guide linear movement in the optical axis direction. The cam barrel 108 has cam grooves having trajectories with different angles in the rotational direction corresponding to the object-side zoom lens unit 110a and the image-side zoom lens unit 110b. On the other hand, each of the object-side zoom lens unit 110a and the image-side zoom lens unit 110b includes cam followers, and each cam follower is engaged with a corresponding one of the linear guide grooves and cam grooves. When the user rotates the zoom operation ring 103, the cam barrel 108 rotates, and the cam followers, through engagement with the linear guide grooves and the cam grooves, advance and retract the object-side zoom lens unit 110a and the image-side zoom lens unit 110b along the optical axis in respective trajectories.

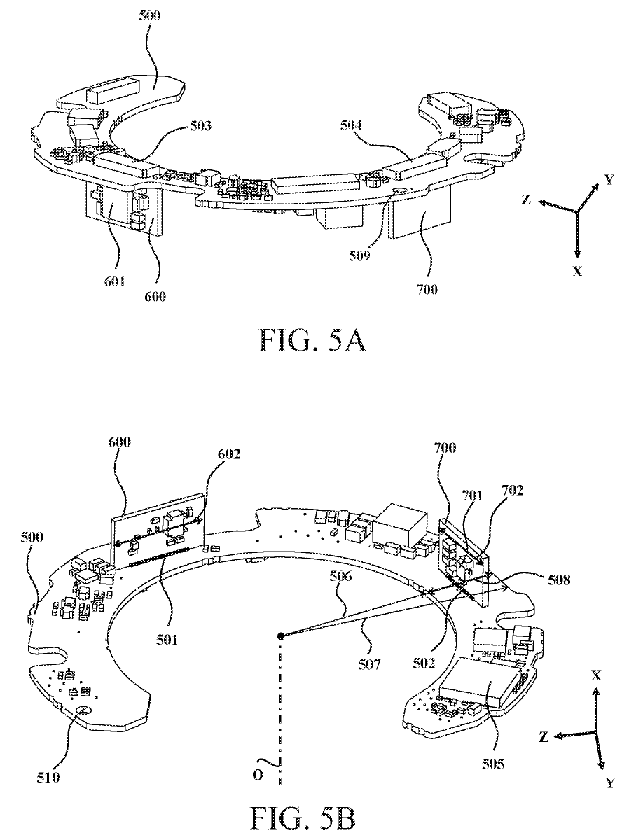

FIGS. 5A and 5B are perspective views illustrating a state in which a first substrate 500, a second substrate 600, and a third substrate 700 constituting the lens control unit 104 are joined to one another. FIGS. 5A and 5B respectively show views seen from different viewpoints.

The first substrate 500 has a principal plane that is approximately perpendicular to the optical axis O. The second substrate 600 has a principal plane that is approximately parallel to the optical axis O. The third substrate 700 has a principal plane that is approximately parallel to the optical axis O. Here, “approximately perpendicular” or “approximately parallel” is not limited to a configuration in which each substrate is strictly perpendicular or parallel to the optical axis O, but includes configurations that are evaluated as being substantially perpendicular or parallel.

Reference numeral 501 denotes a first joint portion that joins the first substrate 500 and the second substrate 600 by soldering. Reference numeral 502 denotes a second joint portion that joins the first substrate 500 and the third substrate 700 by soldering. Reference numeral 503 denotes a first connector that is a connector with an FPC (not illustrated). The FPC will be described later. Reference numeral 504 denotes a second connector that is a connector with the FPC. Reference numeral 505 denotes a microcontroller, which is an electrical element.

Reference numeral 506 denotes a first-substrate inner-diameter as an inner diameter of the first substrate 500. Reference numeral 507 denotes a first-substrate outer-diameter as an outer diameter of the first substrate 500. Reference numeral 508 denotes a first-substrate width corresponding to a difference between the outer diameter (first-substrate outer-diameter 507) and the inner diameter (first-substrate inner-diameter 506) of the first substrate 500 having the same center. Reference numeral 509 denotes a first screw hole for fixing the first substrate 500 inside the interchangeable lens 101. Reference numeral 510 denotes a second screw hole for fixing the first substrate 500 inside the interchangeable lens 101.

Reference numeral 601 denotes an image-stabilization drive Integrated Circuit (IC) that controls the image-stabilization drive unit 402 illustrated in FIG. 2. The image-stabilization drive IC 601 is an electrical element. Reference numeral 602 denotes a second-substrate width corresponding to a contact length between the second substrate 600 and the first substrate 500. Reference numeral 701 denotes a focus drive IC that controls the focus drive unit 302 illustrated in FIG. 2. The focus drive IC 701 is an electrical element. Reference numeral 702 denotes a third-substrate width corresponding to a contact length between the third substrate 700 and the first substrate 500.

The first connector 503, the second connector 504, and the microcontroller 505 are mounted on a principal plane of the first substrate 500. The first-substrate inner-diameter 506 and the first-substrate outer-diameter 507 have the same center (optical axis O). The first substrate 500 has an arcuate shape, and a center of the substrate is located on the optical axis O of a lens, which is an optical element. The image-stabilization drive IC 601 is mounted on the second substrate 600. The focus drive IC 701 is mounted on the third substrate 700. The first-substrate width 508 is smaller than each of the second-substrate width 602 and the third-substrate width 702.

Each substrate width may be wider than one side of an IC mounted thereon, which is an electrical element. Accordingly, mounting a large electrical element on the second substrate 600 or the third substrate 700 can narrow the first-substrate width 508. As a result, the first-substrate outer-diameter 507 can be reduced. In addition, soldering the first substrate 500 and the second substrate 600 can reduce a space occupied by a connector for connector connection as compared with connector joining. As a result, the size of the interchangeable lens 101 can be reduced.

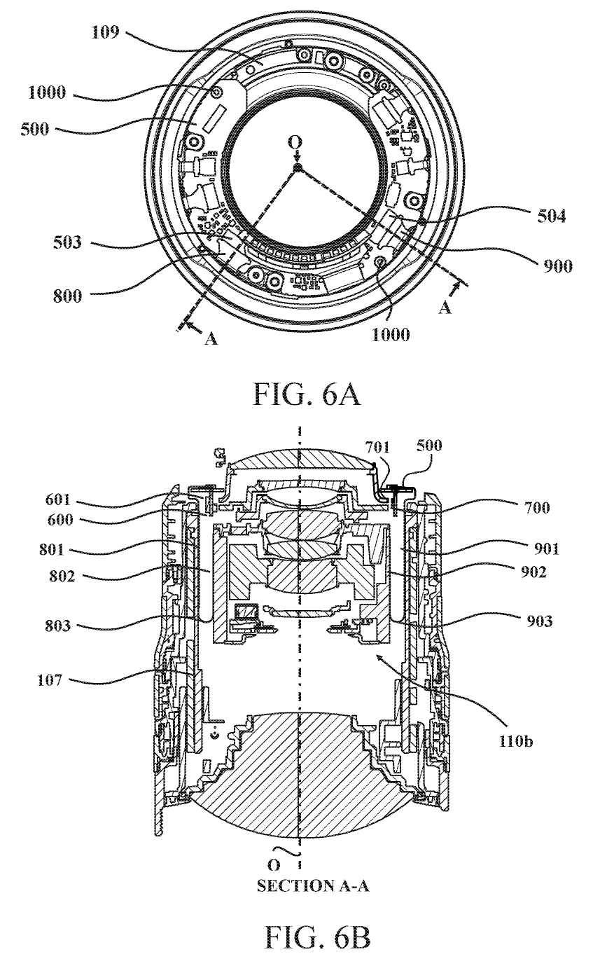

FIG. 6A is a rear view of the interchangeable lens 101 in a state in which the first substrate 500 is exposed. FIG. 6B is a cross-sectional view taken along a line A-A in FIG. 6A. Reference numeral 800 denotes a first FPC electrically connected to the image-stabilization drive unit 402 illustrated in FIG. 2. Reference numeral 801 denotes a first fixed portion at which the first FPC 800 is fixed to the linear guide barrel 107. Reference numeral 802 denotes a first movable portion that moves in accordance with movement of the image-side zoom lens unit 110b. Reference numeral 803 denotes a first bent portion of the first FPC 800.

Reference numeral 900 denotes a second FPC electrically connected to the focus drive unit 302 illustrated in FIG. 2. Reference numeral 901 denotes a second fixed portion at which the second FPC 900 is fixed to the linear guide barrel 107. Reference numeral 902 denotes a second movable portion that moves in accordance with movement of the zoom lens unit 110b. Reference numeral 903 denotes a second bent portion of the second FPC 900.

Reference numeral 1000 denotes a first-substrate fixing screw for fixing the first substrate 500 to the fixed barrel 109. The first FPC 800 is electrically connected to the first substrate 500 via the first connector 503. Control signals from the lens control unit 104 are output to the image-stabilization drive unit 402 via the first FPC 800. The second FPC 900 is electrically connected to the first substrate 500 via the second connector 504. Control signals from the lens control unit 104 are output to the focus drive unit 302 via the second FPC 900.

The second substrate 600 is disposed radially inward of the first fixed portion 801 while the optical axis O serves as a center. The second substrate 600, the first fixed portion 801, and the first movable portion 802 are arranged substantially parallel to one another. Thereby, the second substrate 600 can be disposed in a space formed by the first fixed portion 801, the first bent portion 803, and the first movable portion 802, which will be described later. Therefore, a space-efficient substrate arrangement is achieved, and the size of the interchangeable lens 101 can be reduced.

The third substrate 700 is disposed radially inward of the second fixed portion 901 with respect to the optical axis O. Further, the third substrate 700, the second fixed portion 901, and the second movable portion 902 are arranged approximately parallel to one another. Thereby, the third substrate 700 can be disposed in a space formed by the second fixed portion 901, the second bent portion 903, and the second movable portion 902, which will be described later. Therefore, a space-efficient substrate arrangement is achieved, and the size of the interchangeable lens 101 can be reduced.

As illustrated in FIGS. 6A and 6B, the first substrate 500 is disposed in a dead space on an outer circumference of a lens (optical element) or a lens holding barrel (optical-element holding barrel). Thereby, each substrate can be disposed inside the barrel with high space efficiency, and the size of the interchangeable lens 101 can be reduced. In addition, as illustrated in FIG. 5B, the size of the interchangeable lens 101 is also reduced by reducing the first-substrate outer-diameter 507.

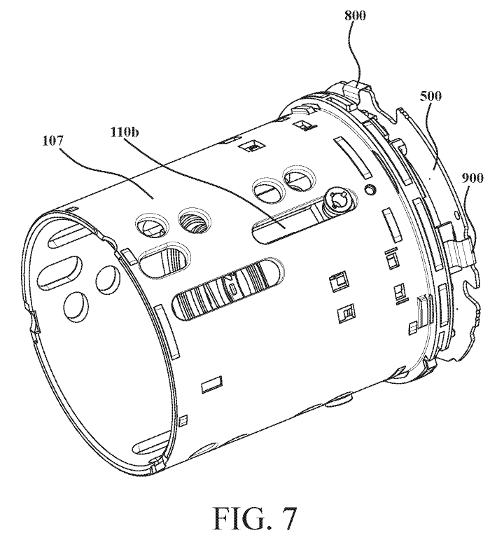

FIG. 7 is a perspective view of the first substrate 500, the image-side zoom lens unit 110b, and the linear guide barrel 107. As illustrated in FIG. 7, the first FPC 800 connected to the first substrate 500 is disposed inside the linear guide barrel 107 and is connected to the image-stabilization drive unit 402 via the image-side zoom lens unit 110b. As illustrated in FIG. 7, the second FPC 900 connected to the first substrate 500 is disposed inside the linear guide barrel 107 and is connected to the focus drive unit 302 via the image-side zoom lens unit 110b.

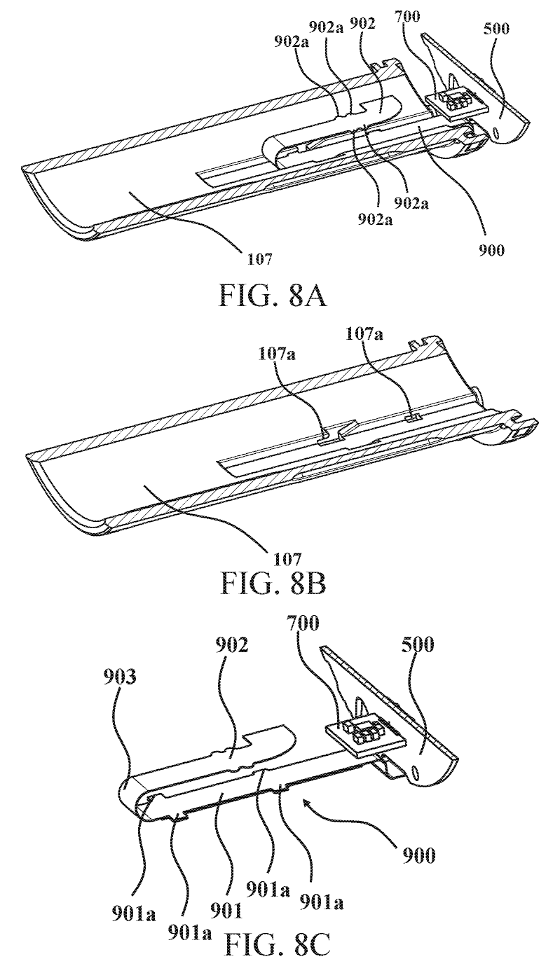

FIGS. 8A to 8C are detailed views of a fixing portion between the linear guide barrel 107 and an FPC (the second FPC 900). FIG. 8A is a perspective view, viewed from inside the linear guide barrel 107, illustrating the second FPC 900, the linear guide barrel 107, the first substrate 500, and the third substrate 700. FIG. 8B is a perspective view, viewed from inside the linear guide barrel 107, illustrating the second FPC 900 and a fixing portion of the linear guide barrel 107. FIG. 8C is a perspective view, viewed from inside the linear guide barrel 107, illustrating the second FPC 900, the first substrate 500, and the third substrate 700.

Reference numeral 901a denotes an engagement portion of the second FPC 900 that is engaged with the linear guide barrel 107. Reference numeral 902a denotes an engagement portion of the second FPC 900 that is engaged with the zoom lens unit 110. Reference numeral 107a denotes an engagement portion of the linear guide barrel 107. As illustrated in FIGS. 8A to 8C, the engagement portion 901a of the second FPC 900 and the engagement portion 107a of the linear guide barrel 107 are engaged with each other, and thereby the second fixed portion 901 is fixed to the linear guide barrel 107. As illustrated in FIG. 8C, the second bent portion 903 is formed by folding back an extended portion of the second fixed portion 901 and extending it toward the second movable portion 902. The first FPC 800 is configured in the same manner as the second FPC 900.

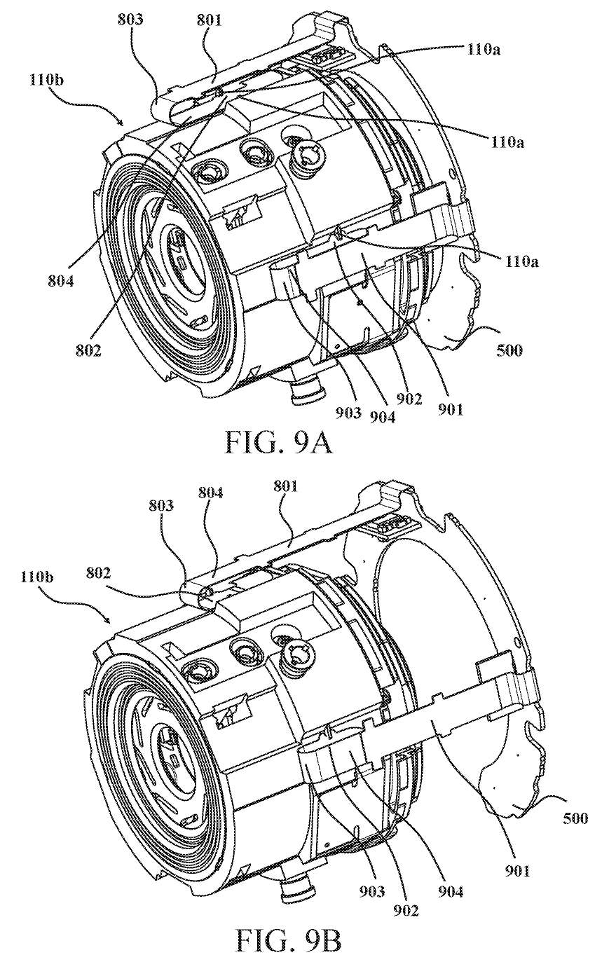

FIGS. 9A and 9B are perspective views of the first substrate 500, the zoom lens unit 110, and the FPCs (the first FPC 800 and the second FPC 900). FIG. 9A illustrates a retracted state of the image-side zoom lens unit 110b. FIG. 9B illustrates an extended state of the image-side zoom lens unit 110b.

With reference to FIGS. 9A and 9B, a space formed by the above-described second fixed portion 901, second bent portion 903, and second movable portion 902 will be described. Reference numeral 904 denotes a slack portion formed between the engagement portion 902a of the second FPC 900 and the second bent portion 903. Reference numeral 804 denotes a slack portion of the first FPC 800, which is formed with a configuration similar to that of the slack portion 904.

As illustrated in FIGS. 9A and 9B, the positions of the slack portions 804 and 904 move, respectively. Thereby, even when the image-side zoom lens unit 110b moves, the first fixed portion 801 and the second fixed portion 901 are not stretched or contracted. As a result, failures due to breakage of the first fixed portion 801 and the second fixed portion 901 can be avoided.

On the other hand, in order to allow movement of the slack portions 804 and 904, the first bent portion 803 and the second bent portion 903 may be provided. Therefore, an arrangement space for the first FPC 800 and the second FPC 900 in a radial direction of the interchangeable lens 101 may be provided. The first FPC 800 and the second FPC 900 extend in the optical-axis direction so as to be capable of following the image-side zoom lens unit 110b that extends in the optical-axis direction. In the present embodiment, the second substrate 600 and the third substrate 700 are disposed in the space formed by the second fixed portion 901, the second bent portion 903, and the second movable portion 902. At this time, the second substrate 600 does not contact the first movable portion 802, and the third substrate 700 does not contact the second movable portion 902. With such a configuration, a space-efficient substrate arrangement is enabled, and the size of the interchangeable lens 101 can be reduced.

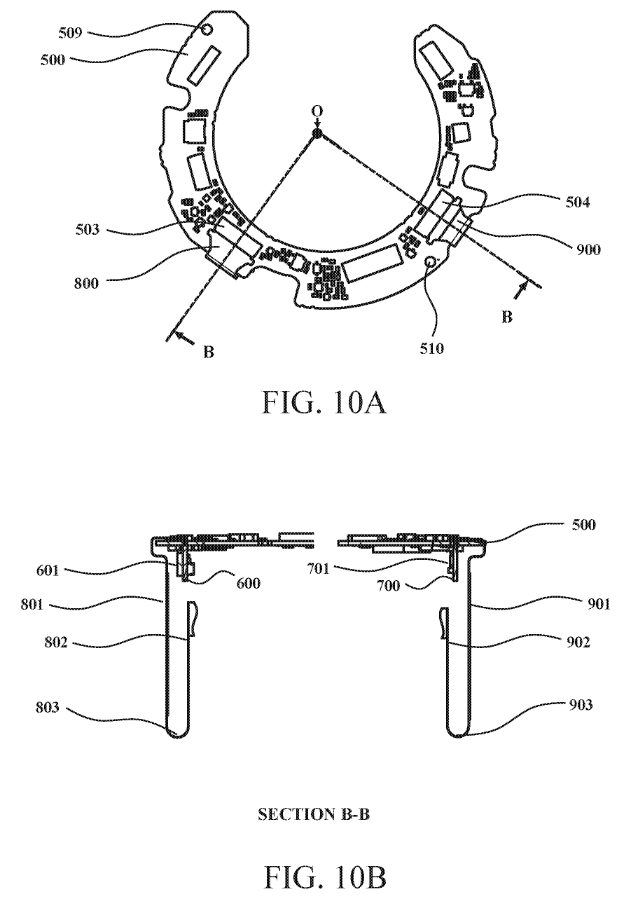

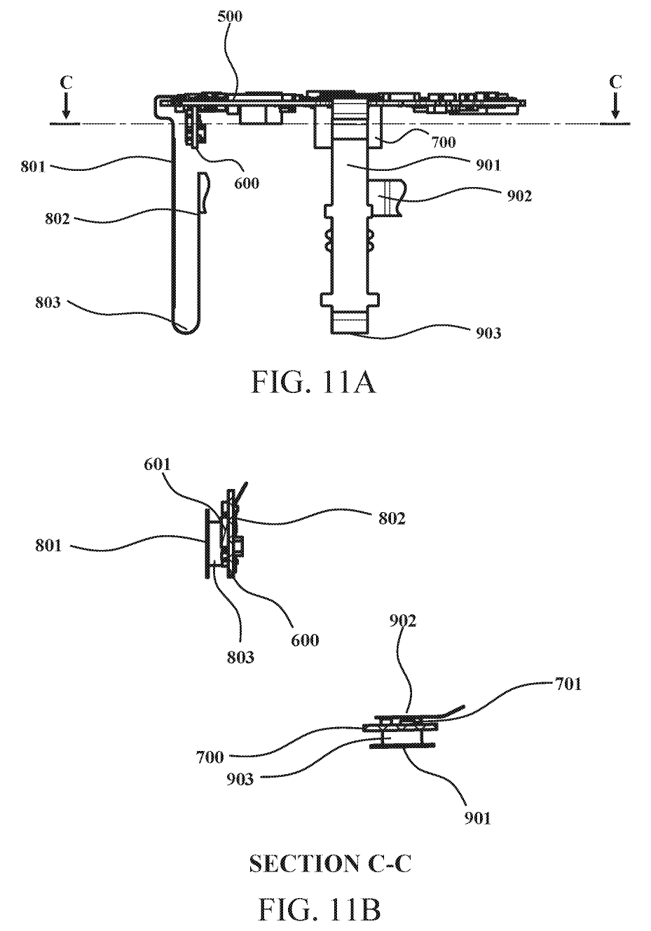

FIG. 10A is a rear view of the first substrate 500, the first FPC 800, and the second FPC 900. FIG. 10B is a cross-sectional view taken along a line B-B in FIG. 10A. FIG. 11A is a side view of the first substrate 500, the second substrate 600, the third substrate 700, the first FPC 800, and the second FPC 900. FIG. 11B is a cross-sectional view taken along a line C-C in FIG. 11A. For convenience of explanation, FIGS. 10A and 10B and FIGS. 11A and 11B will be described together.

As illustrated in FIGS. 10A, 10B, 11A, and 11B, when viewed in the optical-axis direction (on a projection plane orthogonal to the optical axis O), the second substrate 600 is disposed radially inward of the first fixed portion 801 with respect to the optical axis O (at a position closer to the optical axis O). When viewed in the optical-axis direction, the second substrate 600 is disposed so as to overlap the first bent portion 803. When viewed in the optical-axis direction, the second substrate 600 is disposed so as to overlap the first movable portion 802. Thereby, the second substrate 600 can be disposed in the space formed by the first fixed portion 801, the first bent portion 803, and the first movable portion 802. As a result, the second substrate 600 can be disposed with high space efficiency.

As illustrated in FIGS. 10A, 10B, 11A, and 11B, when viewed in the optical-axis direction (on a projection plane orthogonal to the optical axis O), the third substrate 700 is disposed radially inward of the second fixed portion 901 while the optical axis O serves as a center (at a position closer to the optical axis O). When viewed in the optical-axis direction, the third substrate 700 is disposed so as to overlap the second bent portion 903. When viewed in the optical-axis direction, the third substrate 700 is disposed radially outward of the second movable portion 902 while the optical axis O serves as a center (at a position farther from the optical axis O than the second movable portion 902). Thereby, the third substrate 700 can be disposed in the space formed by the second fixed portion 901, the second bent portion 903, and the second movable portion 902. As a result, the third substrate 700 can be disposed with high space efficiency.

With such a configuration, even when the first-substrate width 508 is reduced, electrical elements such as ICs can be mounted by disposing the second substrate 600 and the third substrate 700 using the space described above. Thus, the size of the interchangeable lens 101 can be reduced by reducing the first-substrate width 508.

As illustrated in FIGS. 10A, 10B, 11A, and 11B, when viewed in the optical-axis direction, the image-stabilization drive IC 601 is not disposed between the second substrate 600 and the first movable portion 802. For example, the image-stabilization drive IC 601 is disposed between the second substrate 600 and the first fixed portion 801. Thereby, compared with a case in which the image-stabilization drive IC 601 is disposed between the second substrate 600 and the first movable portion 802, a clearance with surrounding members assumed at a drop impact time can be reduced. Thus, space efficiency is improved, and the size of the interchangeable lens 101 can be reduced.

In each embodiment, for example, the lens control unit 104 may include the first substrate 500 and the second substrate 600 without using the third substrate 700. In each embodiment, the first-substrate width 508 may be larger than the second-substrate width 602 or the third-substrate width 702. In each embodiment, the first FPC 800 or the second FPC 900 may be connected to a fixed lens unit whose position in the optical-axis direction is fixed. In each embodiment, the first substrate 500 may not have a completely arcuate shape, and a part of the first-substrate inner-diameter 506 or the first-substrate outer-diameter 507 may have a different shape such as a straight shape.

As described above, the optical apparatus of the present embodiment can achieve a space-efficient substrate arrangement and layout. Therefore, the present embodiment can provide an optical apparatus having a reduced size.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

In the present embodiment, two substrates (the second substrate 600 and the third substrate 700) that are parallel to the optical axis are joined to the first substrate 500, but the configuration is not limited to this example. For example, only one substrate, or three or more substrates, may be joined to the first substrate 500. The second substrate 600 and the third substrate 700 are interchangeable, and at least one of the two substrates may be referred to as the first substrate.

What is claimed is:

1. An optical apparatus comprising:
a first substrate having a principal plane perpendicular to an optical axis;
a second substrate having a principal plane parallel to the optical axis; and
a flexible printed circuit,
wherein the first substrate and the second substrate are joined to each other, and
wherein, when viewed in an optical-axis direction, the second substrate overlaps the flexible printed circuit.

2. The optical apparatus according to claim 1, further comprising a lens unit movable in the optical-axis direction,
wherein the flexible printed circuit is electrically connected to the lens unit.

3. The optical apparatus according to claim 1, wherein the flexible printed circuit includes a fixed portion, a movable portion, and a bent portion.

4. The optical apparatus according to claim 3, wherein, when viewed in the optical-axis direction, the second substrate is disposed closer to the optical axis than the fixed portion.

5. The optical apparatus according to claim 3, wherein, when viewed in the optical-axis direction, the second substrate overlaps the bent portion.

6. The optical apparatus according to claim 3, wherein, when viewed in the optical-axis direction, the second substrate overlaps the movable portion.

7. The optical apparatus according to claim 3, wherein, when viewed in the optical-axis direction, the second substrate is disposed farther from the optical axis than the movable portion.

8. The optical apparatus according to claim 3, wherein the second substrate does not contact the movable portion.

9. The optical apparatus according to claim 1, wherein the first substrate has a first-substrate width corresponding to a difference between an outer diameter and an inner diameter having a same center,
wherein the second substrate has a second-substrate width corresponding to a contact length with the first substrate, and
wherein the first-substrate width is smaller than the second-substrate width.

10. The optical apparatus according to claim 1, further comprising an electrical element mounted on the second substrate.

11. The optical apparatus according to claim 1, wherein, when viewed in the optical-axis direction, the first substrate is disposed on an outer circumference of an optical element or an optical-element holding barrel.

12. The optical apparatus according to claim 10, wherein, when viewed in the optical-axis direction, the electrical element is not disposed between the second substrate and a movable portion of the flexible printed circuit.

13. The optical apparatus according to claim 1, wherein the first substrate and the second substrate are joined to each other by solder.

14. The optical apparatus according to claim 1, wherein the optical apparatus is a lens apparatus.

15. The optical apparatus according to claim 1, wherein the optical apparatus is an image pickup apparatus.
